(19) United States
(12) Patent Application Publication
(10) Pub. No.: US 2026/0078525 A1
(43) Pub. Date: Mar. 19, 2026

(54) SUSCEPTOR AND SIC EPITAXIAL GROWTH APPARATUS

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tsutomu KIYOSAWA, Himeji (JP); Masaharu SHIMABAYASHI, Ibo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/058,159

(22) Filed: Feb. 20, 2025

(30) Foreign Application Priority Data
Sep. 18, 2024 (JP) 2024-160848

(51) Int. Cl. C30B 25/12; C23C 16/32; C23C 16/458; C30B 29/36; H01L 21/687

(52) U.S. Cl. CPC C30B 25/12; C23C 16/325; C23C 16/4584; C23C 16/4586; C30B 29/36; H10P 72/7606

(57) ABSTRACT

A susceptor of an embodiment includes a support base and an annular wafer guide. The support base has a support surface for supporting the wafer. The wafer guide surrounds the periphery of the wafer. When viewed from an axial direction of the center axis, the inner peripheral surface of the wafer guide is provided with an arc portion and a rotation stopper portion. The arc portion extends on a virtual circle centered on the center axis. The rotation stopper portion is located radially inside the virtual circle. The rotation stopper portion has a tip portion and a side portion. The tip portion is located at the radially inner end of the rotation stopper portion. The side portion is located on at least one side of the tip portion in a circumferential direction centered on the center axis. The side portion is connected to the arc portion.

### CROSS-REFERENCE TO RELATED APPLICATION

This application is based upon and claims the benefit of priority from Japanese Patent Application No. 2024-160848, filed on Sep. 18, 2024, the entire contents of which are incorporated herein by reference.

### FIELD

Embodiments described herein relate generally to a susceptor and a SiC epitaxial growth apparatus.

### BACKGROUND

In a susceptor of a SiC epitaxial growth apparatus, a wafer guide is disposed around a wafer supported on a support surface. The wafer guide is provided with a flat portion that faces a flat portion of the wafer to suppress the rotation of the wafer. When the wafer guide thermally shrinks, the wafer may be caught between the flat portion and the inner peripheral surface on the opposite side. As a result, it is difficult to transport the wafer.

### BRIEF DESCRIPTION OF THE DRAWINGS

FIG. 1 is a cross-sectional view showing a SiC epitaxial growth apparatus of an embodiment.

FIG. 2 is a plan view showing a wafer guide of an embodiment.

FIG. 3 is a plan view showing a wafer guide of a first modified example.

FIG. 4 is a plan view showing a wafer guide of a second modified example.

FIG. 5 is a plan view showing a wafer guide of a third modified example.

FIG. 6 is a plan view showing a wafer guide of a fourth modified example.

FIG. 7 is a plan view showing a wafer guide of a comparative example.

### DETAILED DESCRIPTION

A susceptor of an embodiment includes a support base and an annular wafer guide. The support base has a support surface for supporting the wafer. The wafer guide surrounds the periphery of the wafer supported on the support surface with the center axis extending in a normal direction of the support surface as the center. When viewed from an axial direction of the center axis, the inner peripheral surface of the wafer guide is provided with an arc-shaped arc portion and a rotation stopper portion. The arc portion extends on a virtual circle centered on the center axis. The rotation stopper portion is located radially inside the virtual circle. The rotation stopper portion has a tip portion and a side portion. The tip portion is located at the radially inner end of the rotation stopper portion. The side portion is located on at least one side of the tip portion in a circumferential direction centered on the center axis. The side portion extends radially outward from the tip portion. The side portion is connected to the arc portion.

Hereinafter, a susceptor and a SiC epitaxial growth apparatus according to an embodiment will be described with reference to the drawings. In the following description, components having the same or similar functions are denoted by the same reference numerals. Then, duplicate descriptions of those components may be omitted.

A configuration of the SiC epitaxial growth apparatus will be described below.

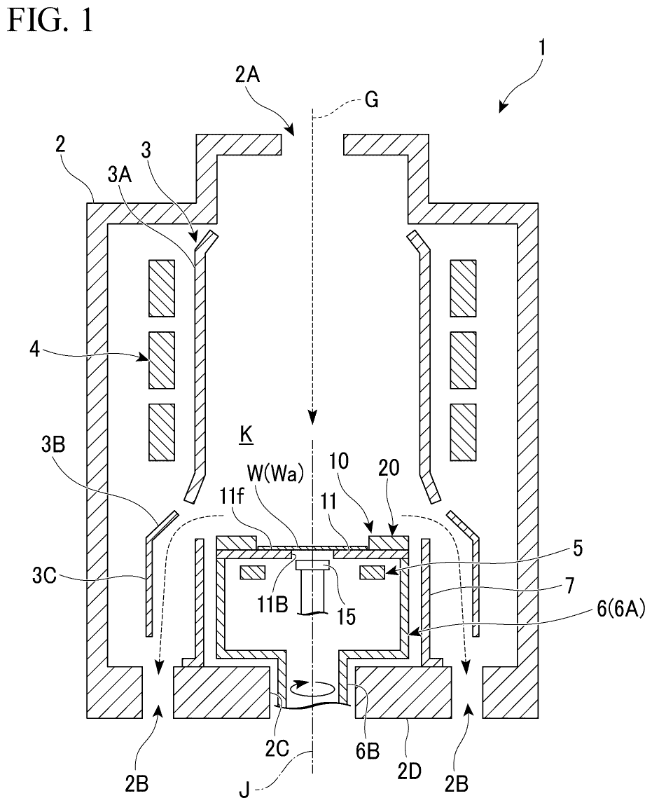

FIG. 1 is a cross-sectional view of a SiC epitaxial growth apparatus 1 having a susceptor 10 of the embodiment.

In the following description, the side into which the supplied source gas flows is referred to as the upper side, and the side from which the source gas flows is referred to as the lower side. In each figure, the center axis J of the susceptor 10 is illustrated. In the following description, the axial direction of the center axis J may be simply referred to as the “axial direction.” The radial direction centered on the center axis J may be simply referred to as the “radial direction.” Furthermore, the circumferential direction around the center axis J may be simply referred to as the “circumferential direction.”

As shown in FIG. 1, the SiC epitaxial growth apparatus 1 grows an epitaxial film that will become an active region on a wafer W made of silicon carbide (SiC) by chemical vapor deposition (thermal CVD) or the like. The SiC epitaxial growth apparatus 1 includes a chamber 2, a reactor member 3, an upper heater 4, a lower heater 5, a rotating cylinder 6, a partition cylinder 7, the susceptor 10, and a lifting unit 15.

The chamber 2 is made of a metal material such as stainless steel (SUS). The chamber 2 accommodates therein the reactor member 3, the upper heater 4, the lower heater 5, the rotating cylinder 6, the partition cylinder 7, and the susceptor 10. The chamber 2 has an introduction port 2A, an exhaust port 2B, and an insertion port 2C.

The introduction port 2A is provided on the top plate of the chamber 2. Further, the exhaust port 2B and the insertion port 2C are provided in a bottom 2D of the chamber 2. The introduction port 2A is formed to open at the upper end of the chamber 2. The introduction port 2A is a point where gases used, including a source gas G, supplied from above along the center axis J, are introduced into the chamber 2. The exhaust port 2B is a point where gases used, including the source gas G used in the SiC epitaxial growth process, are exhausted.

The source gas G reacts on the wafer W to form an epitaxial film. The source gas G is, for example, a Si-based gas and a C-based gas. The Si-based gas is, for example, silane (SiH₄), dichlorosilane (SiH₂Cl₂), trichlorosilane (SiHCl₃), or tetrachlorosilane (SiCl₄). The C-based gas is, for example, propane (C₃H₈). The source gas G in the embodiment is, for example, SiH₄+C₃H₈ (flow rate: several tens to several hundreds sccm).

Examples of gases used in addition to the source gas G include impurity gases, carrier gases, and other gases. Examples of impurity gases include N₂ (N-type impurity) and TMA (P-type impurity) (flow rate: several to several hundred sccm). Examples of carrier gases include H₂ (during growth) and Ar (during transportation) (flow rate: 100 to 200 slm). Examples of other gases include HCl (for suppressing particles during growth, high-speed growth) (flow rate: from several tens of sccm to several hundreds of slm).

The reactor member 3 constitutes a furnace. The reactor member 3 is made of graphite, for example. The reactor member 3 may have an inner surface coated with SiC or TaC to prevent dust generation. The reactor member 3 has a first cylindrical portion 3A, a tapered portion 3B, and a second cylindrical portion 3C.

The first cylindrical portion 3A is located at the upper side in the reactor member 3. The first cylindrical portion 3A is open below the introduction port 2A of the chamber 2. Gases including the source gas G introduced from the introduction port 2A are introduced into the inner space of the reactor member 3. The inner space of the reactor member 3 is a film formation space K.

The tapered portion 3B extends radially outward as it goes downward from the lower end of the first cylindrical portion 3A. The second cylindrical portion 3C extends downward from the lower end of the tapered portion 3B. The radial position of the second cylindrical portion 3C is located on the outside of the exhaust port 2B of the chamber 2 in the radial direction. The tapered portion 3B is disposed in a range including an axial position of a first surface Wa of the wafer W facing upward in the up and down direction. Thus, the gas including the source gas G introduced into the film formation space K from the introduction port 2A flows radially outward along the first surface Wa after reaching the wafer W. The gas containing the source gas G that has flowed radially outward from the wafer W is guided to the tapered portion 3B and the second cylindrical portion 3C and is exhausted from the exhaust port 2B of the chamber 2.

The upper heater 4 surrounds the outer periphery of the first cylindrical portion 3A of the reactor member 3 in the circumferential direction. The upper heater 4 extends in the axial direction along the first cylindrical portion 3A. The lower heater 5 is disposed below the susceptor 10 to be away from the susceptor 10. As an example, the lower heater 5 has an annular shape extending in the circumferential direction. Due to the heating of the upper heater 4 and the lower heater 5, the wafer W is heated, for example, in a range of 1500 to 1650° C. The upper heater 4 and the lower heater 5 may be of known construction.

The rotating cylinder 6 is rotatable in the circumferential direction. The rotating cylinder 6 has a first rotating cylinder 6A and a second rotating cylinder 6B. The first rotating cylinder 6A is provided above the second rotating cylinder 6B. The first rotating cylinder 6A is disposed above the bottom 2D in the chamber 2. The lower heater 5 is disposed inside the first rotating cylinder 6A. The diameter of the first rotating cylinder 6A is larger than the diameter of the second rotating cylinder 6B. The second rotating cylinder 6B extends downward from the first rotating cylinder 6A. The second rotating cylinder 6B is inserted into the insertion port 2C.

The partition cylinder 7 is fixed to the bottom 2D of the chamber 2. The partition cylinder 7 extends upward along the axial direction. The partition cylinder 7 is disposed radially inward of the second cylindrical portion 3C and spaced apart radially outward from the first rotating cylinder 6A.

The lifting unit 15 is capable of moving up and down in the axial direction between a lowered position and an elevated position. The lifting unit 15 in the lowered position is located below the susceptor 10. The lifting unit 15 moves from the lowered position to the elevated position to lift up the wafer W mounted on the susceptor 10 via a through hole 11B of the susceptor 10.

The susceptor 10 includes a support base 11 and a wafer guide 20. The susceptor 10 supports the wafer W on a support surface 11f of the support base 11. The support surface 11f is perpendicular to the center axis J. That is, the normal direction of the support surface 11f extends parallel to the center axis J.

The support base 11 has a disk shape centered on the center axis J. The support base 11 is fixed to the rotating cylinder 6. The support base 11 rotates together with the rotating cylinder 6 about the center axis J. The support base 11 has the support surface 11f and the through hole 11B. The support surface 11f supports the wafer W from below radially outward of the through hole 11B. The through hole 11B penetrates the support base 11 in the axial direction with the center axis J as the center.

The wafer guide 20 is joined and fixed to the support surface 11f of the support base 11. The wafer guide 20 rotates around the center axis J together with the support base 11.

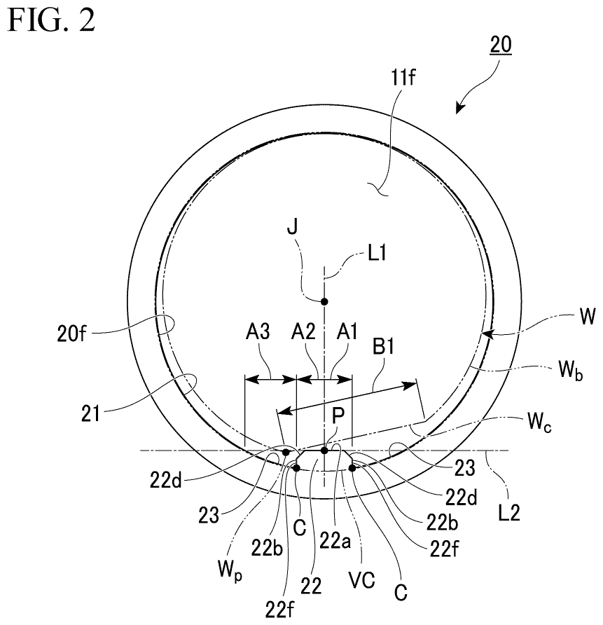

FIG. 2 is a plan view of the wafer guide 20 of this embodiment. In FIG. 2, the wafer W disposed radially inside the wafer guide 20 is indicated by a two-dot chain line.

The outer shape of the wafer W is approximately circular, and a linear flat portion Wc is provided in part of the wafer W to indicate the crystal orientation of the wafer W. That is, the outer peripheral surface of the wafer W is provided with an arc outer peripheral portion Wb extending in an arc shape when viewed in the axial direction, and the flat portion Wc extending in a straight line when viewed in the axial direction.

The flat portion Wc is connected to one end and the other end of the arc outer peripheral portion Wb in the circumferential direction. A corner Wp is provided at the boundary between the arc outer peripheral portion Wb and the flat portion Wc. Two corners Wp are provided on the outer periphery of the wafer W.

The wafer guide 20 has an annular shape centered on the center axis J and surrounding the periphery of the wafer W supported on the support surface 11f.

The wafer guide 20 has an inner peripheral surface 20f which faces the outer peripheral surface of the wafer W in the radial direction. The inner peripheral surface 20f is provided with an arc portion 21 and a rotation stopper portion 22.

The arc portion 21 extends in an arc shape around the center axis J with a constant radius in the circumferential direction. The radius of the arc portion 21 is slightly larger than the radius of the wafer W. The arc portion 21 surrounds the outer peripheral surface of the wafer W from the outside in the radial direction. Accordingly, the arc portion 21 guides the outer peripheral surface of the wafer W during the film formation process, and prevents the wafer W from coming off the support surface 11f.

As shown in FIG. 2, a virtual circle VC is assumed to be centered on the center axis J when viewed from the axial direction. The radius of the virtual circle VC is equal to the radius of the arc portion 21. Therefore, the virtual circle VC extends on the arc portion 21.

The rotation stopper portion 22 is located radially inside the virtual circle VC. The rotation stopper portion 22 of this embodiment protrudes radially inward with respect to the arc portion 21. The rotation stopper portion 22 of this embodiment has a substantially rectangular shape when viewed from the axial direction. The rotation stopper portion 22 has a tip surface (tip portion) 22a and a pair of side portions 22b.

The tip surface 22a is located at a radially inner end of the rotation stopper portion 22. In this embodiment, the tip surface 22a is a flat surface that faces radially inward.

The side portions 22b are located on one side and the other side of the tip surface 22a in the circumferential direction. The pair of side portions 22b are connected to the tip surface 22a. The side portions 22b extend radially outward from the tip surface 22a.

The side portion 22b has a chamfered portion 22d and a side surface 22f. The side surface 22f is a flat surface perpendicular to the tip surface 22a. One of the pair of side surfaces 22f faces one circumferential side, and the other faces the other circumferential side. The chamfered portion 22d connects the tip surface 22a and the side surface 22f. The chamfered portion 22d is inclined with respect to both the tip surface 22a and the side surface 22f.

Since the support surface 11f is formed to be smooth, the wafer W may slide and rotate on the support surface 11f. In addition, reaction products may accumulate not only on the upper surface of the wafer W but also on the area of the support surface 11f on which the wafer W is not mounted through the film formation process. Therefore, when the wafer W slides and rotates to move on the support surface 11f, the reaction products deposited on the support surface 11f may adhere to the rear surface of the wafer W. If the movement of the wafer W on the support surface 11f is large, the amount of reaction products adhering to the rear surface of the wafer W also increases to thereby cause a problem that the front surface of the wafer W may be tilted in a later process.

The wafer guide 20 of this embodiment has the rotation stopper portion 22 on the inner peripheral surface 20f. Therefore, when the wafer W is mounted onto the support surface 11f, the flat portion Wc of the wafer W is opposed to the tip surface 22a of the rotation stopper portion 22, so that the rotation of the wafer W is restricted even when the wafer W slides on the support surface 11f.

As shown in FIG. 2, the point located most radially inside the rotation stopper portion 22 is defined as a tip point P. The tip point P is located on the tip surface 22a. Further, when viewed from the axial direction, a straight line connecting the tip point P and the central axis J is defined as a first reference line L1. Further, when viewed from the axial direction, a straight line passing through the tip point P and perpendicular to the first reference line is defined as a second reference line L2. According to the wafer guide 20 of this embodiment, the rotation stopper portion 22 has the side portions 22b located on one side and the other side of the tip surface 22a in the circumferential direction and extending radially outward from the tip surface 22a. For this reason, an escape concave portion 23 is provided on the inner peripheral surface 20f of the wafer guide 20 to be located radially outward with respect to the second reference line L2.

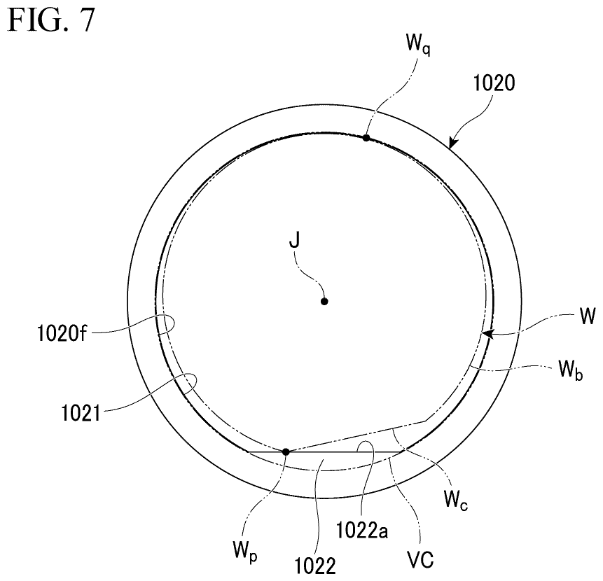

FIG. 7 is a plan view of a comparative example of a wafer guide 1020. The operations and effects of this embodiment will be described by the comparison with the comparative example.

As shown in FIG. 7, an inner peripheral surface 1020f of the wafer guide 1020 of the comparative example is provided with an arc portion 1021 and a rotation stopper portion 1022. The arc portion 1021 extends in the circumferential direction on the virtual circle VC. The rotation stopper portion 1022 is located radially inside the virtual circle VC. The rotation stopper portion 1022 has a tip surface 1022a that faces radially inward. The tip surface 1022a is a flat surface that extends linearly. Both circumferential ends of the tip surface 1022a are connected to the arc portion 1021.

When the wafer W rotates on the support surface 11f, the wafer guide 1020 of the comparative example restricts the rotation of the wafer W by bringing the corner Wp of the wafer W into contact with the tip surface 1022a. In this case, the wafer W also comes into contact with the wafer guide 1020 at a contact point Wq on the opposite side of the center of the wafer W from the corner Wp. Further, since the temperature in the chamber 2 is increased to form the film in the film formation process, the wafer guide 1020 may thermally shrink due to heat dissipation after the film formation process, and the wafer W may be caught in the wafer guide 1020. In this case, since the wafer W is less likely to be separated from the wafer guide 1020, it is difficult to unload the wafer W from the susceptor 10.

As shown in FIG. 2, according to this embodiment, the inner peripheral surface 20f of the wafer guide 20 is provided with the arc portion 21 and the rotation stopper portion 22 when viewed from the axial direction. The arc portion 21 has an arc shape extending on the virtual circle VC centered on the central axis J. At least a part of the rotation stopper portion 22 is located radially inside the virtual circle VC. The rotation stopper portion 22 has the tip surface 22a and the side portion 22b. The tip surface 22a is located at the radially inner end of the rotation stopper portion 22. The side portion 22b is located on at least one circumferential side of the tip surface 22a. The side portion 22b extends radially outward from the tip surface 22a. The side portion 22b is connected to the arc portion 21. According to this configuration, the escape concave portion 23 which is recessed radially outward from the rotation stopper portion 22 can be formed on at least one circumferential side of the rotation stopper portion 22. Therefore, when the wafer W rotates inside the wafer guide 20, the flat portion Wc can be brought into contact with the rotation stopper portion 22, and the corner Wp can be disposed inside the escape concave portion 23. Therefore, even when the wafer guide 20 thermally shrinks, the wafer W can be suppressed from being caught in the inner peripheral surface 20f of the wafer guide 20. Accordingly, after the film formation process, the wafer W can be smoothly unloaded from the susceptor 10. That is, according to this embodiment, the susceptor 10 capable of suppressing interference with unloading of the wafer W can be provided.

As shown in FIG. 2, the rotation stopper portion 22 and the virtual circle VC intersect with each other at two intersections C on one side and the other side in the circumferential direction. Here, the distance between the two intersections C is defined as the width dimension A2 of the rotation stopper portion 22. It is preferable that the width dimension A2 of the rotation stopper portion 22 is shorter than the length dimension B1 of the flat portion Wc of the wafer W when viewed in the axial direction. In this case, when the wafer W rotates, the corners Wp of the wafer W can be more easily positioned in the escape concave portions 23, and the wafer W can be more easily suppressed from being caught by the wafer guides 20.

In this embodiment, it is preferable that the width dimension A3 of the escape concave portion 23 along the second reference line L2 is 50% or more of the width dimension A2 of the rotation stopper portion 22. In this case, the corner Wp of the wafer W can be easily disposed in the escape concave portion 23 by ensuring that the escape concave portion 23 is sufficiently large with respect to the tip surface 22a of the rotation stopper portion 22. Accordingly, even when the dimensions of each part of the wafer W are slightly changed within the range that fits inside the wafer guide 20, the wafer guide 20 that can suppress the wafer W from being caught can be provided.

In this embodiment, the side portions 22b are provided on one side and the other side of the tip surface 22a in the circumferential direction, respectively. According to this embodiment, the escape concave portion 23 can be formed on both sides of the rotation stopper portion 22 in the circumferential direction. According to this embodiment, even when the wafer W rotates on the support surface 11f in any direction, the corner Wp can be disposed in one of the escape concave portions 23 to suppress the wafer W from being caught by the inner peripheral surface 20f. In particular, the two escape concave portions 23 in this embodiment are arranged in mirror symmetry with respect to the first reference line L1. Therefore, even when the wafer W rotates in any direction, the corner Wp can be retreated to the escape concave portion 23 in the same manner.

According to this embodiment, the side portion 22b has the chamfered portion 22d provided at a portion connected to the tip surface 22a. That is, the rotation stopper portion 22 of this embodiment has the chamfered portion 22d at the corner. Therefore, the rotation of the wafer W can be restricted by contacting the chamfered portion 22d of the rotation stopper portion 22. That is, according to this embodiment, the flat portion Wc of the wafer W does not come into contact with the corners of the rotation stopper portion 22, and the application of a large local force to the wafer W can be suppressed.

Furthermore, the corners of the rotation stopper portion 22 may be provided with curved surfaces instead of the chamfered portions 22d.

### First Modified Example

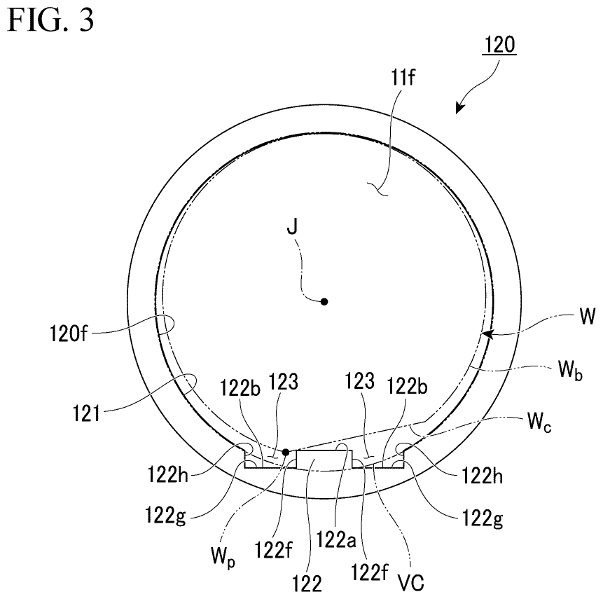

FIG. 3 is a plan view of a wafer guide 120 of a first modified example that can be used in the susceptor 10 of the above-described embodiment. The wafer guide 120 of this modified example differs from the above-described embodiment mainly in the shape of a side portion 122b.

As in the above-described embodiment, an inner peripheral surface 120f of the wafer guide 120 is provided with an arc portion 121 which extends on the virtual circle VC and a rotation stopper portion 122 which is located radially inside the virtual circle. The rotation stopper portion 122 has a tip surface (tip portion) 122a and a pair of side portions 122b. The tip surface 122a is a flat surface that is located at the radially inner end of the rotation stopper portion 122 and faces radially inward.

The side portions 122b of this modified example are located on one side and the other side of the tip surface 122a in the circumferential direction. The pair of side portions 122b are respectively connected to the tip surface 122a. The side portion 122b extends radially outward from the tip surface 122a.

The side portion 122b has a first side surface 122f, a second side surface 122h, and a third side surface 122g. The first side surface 122f and the second side surface 122h face each other. The first side surface 122f and the second side surface 122h extend along the radial direction. The first side surface 122f is connected to the tip surface 122a. The second side surface 122h is connected to the arc portion 121. The third side surface 122g faces radially inward. The third side surface 122g is connected to the radially outer end of the first side surface 122f. The third side surface 122g is connected to the radially outer end of the second side surface 122h.

According to this modified example, the side portion 122b extends radially outward from the tip surface 122a in the first side surface 122f. Further, the side portion 122b is connected to the arc portion 121 in the second side surface 122h. Therefore, as in the above-described embodiment, the inner peripheral surface 120f of the wafer guide 120 of this modified example can be provided with an escape concave portion 123 capable of accommodating the corner Wp of the wafer W. Accordingly, the wafer W can be suppressed from being caught in the inner peripheral surface 120f of the wafer guide 120. The escape concave portion 123 of this modified example spreads radially outward with respect to the virtual circle VC. Even when such an escape concave portion 123 is formed, the same effects as those of the above-described embodiment can be obtained.

### Second Modified Example

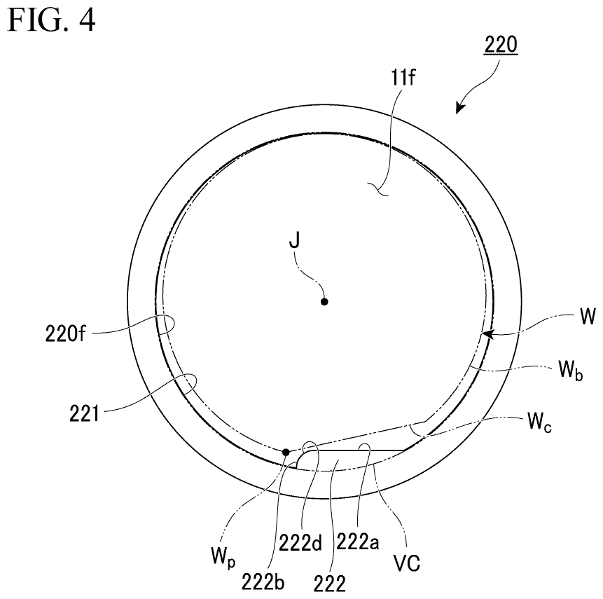

FIG. 4 is a plan view of a wafer guide 220 of a second modified example that can be used in the susceptor 10 of the above-described embodiment. The wafer guide 220 of this modified example differs from the above-described embodiment mainly in that the rotation stopper portion 222 has only one side portion 222b and the side portion 222b has a curved surface 222d.

An inner peripheral surface 220f of the wafer guide 220 is provided with an arc portion 221 which extends on the virtual circle VC and a rotation stopper portion 222 which is located radially inside the virtual circle. The rotation stopper portion 222 has a tip surface (tip portion) 222a and a side portion 222b. In this modified example, the side portion 222b is provided on only one circumferential side of the tip surface 222a. Further, the other circumferential end of the tip surface 222a is connected to the arc portion 221.

In this modified example, the side portion 222b is provided on only one circumferential side of the rotation stopper portion 222. In a typical film formation process, the rotating cylinder 6 (see FIG. 1) rotates in one direction. Further, the wafer W is caught by the wafer guide during heat dissipation after the film formation process. The wafer W on the support surface 11f slides in the rotation direction of the rotating cylinder 6 due to the inertial force caused by the stopping of the rotating cylinder 6. Therefore, the rotational deviation of the wafer W during heat dissipation is basically in one direction. According to this modified example, it is possible to suppress the wafer W from being caught by the wafer guide 220 by arranging the side portion 222b in accordance with the rotation direction of the rotating cylinder 6. The side portion 222b is formed, for example, by a cutting process. According to this modified example, since the number of the side portions 222b is decreased, the time required for the cutting process during the manufacture of the wafer guide 220 can be shortened, and the manufacturing cost of the susceptor 10 can be reduced.

The side portion 222b of this modified example has the curved surface 222d. The curved surface 222d has a convex arc surface. The radially inner end of the curved surface 222d is connected to the tip surface 222a. Further, the radially outer end of the curved surface 222d is connected to the arc portion 221.

Since the curved surface 222d of this modified example is smoothly connected to the tip surface 222a, the formation of corners in the rotation stopper portion 222 is suppressed. According to this modified example, since the rotation stopper portion 222 does not have corners and the wafer W is brought into contact with the curved surface 222d during the rotation of the wafer W, the rotation of the wafer W can be restricted. Therefore, the application of a large local force to the flat portion Wc of the wafer W can be suppressed. Furthermore, the corners of the rotation stopper portion 222 may be provided with chamfered portions instead of the curved surface 222d.

### Third Modified Example

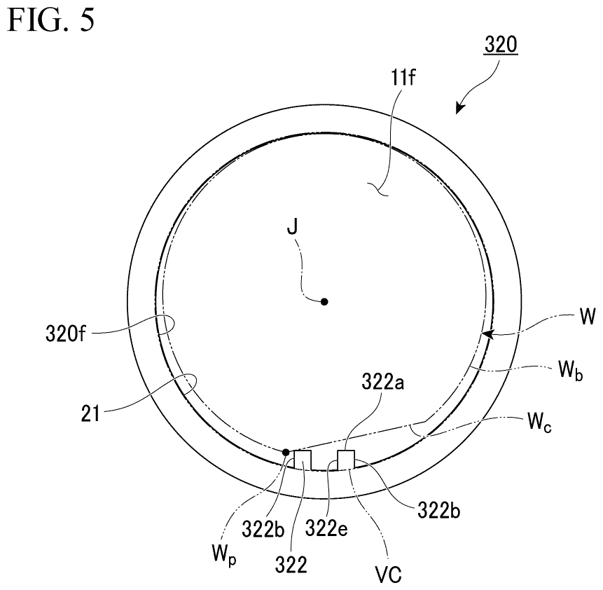

FIG. 5 is a plan view of a wafer guide 320 of a third modified example that can be used in the susceptor 10 of the above-described embodiment. The wafer guide 320 of this modified example differs from the above-described embodiment mainly in that a concave portion 322e is provided in a rotation stopper portion 322.

As in the above-described embodiment, an inner peripheral surface 320f of the wafer guide 320 of this modified example is provided with the arc portion 21 which extends on the virtual circle VC and a rotation stopper portion 322 which is located radially inside the virtual circle.

As in the above-described embodiment, the rotation stopper portion 322 of this modified example includes a tip surface (tip portion) 322a which faces radially inward and a pair of side portions 322b. The tip surface 322a of this modified example is provided with a concave portion 322e which is recessed radially outward. The concave portion 322e is provided at the circumferential center of the tip surface 322a. The radially outer end of the concave portion 322e of this modified example extends in an arc shape along the virtual circle VC. However, the position and shape of the radially outer end of the concave portion 322e are not limited to this modified example.

In the film formation process, reaction products accumulate not only on the upper surface of the wafer W but also on the upper surface of the wafer guide 320. In particular, since the rotation stopper portion 322 is located radially inward and close to the wafer W, reaction products tend to accumulate on the upper surface of the rotation stopper portion 322. The deposits on the upper surface of the rotation stopper portion 322 may adhere to the wafer W when the wafer W is loaded or transported. According to this modified example, the rotation stopper portion 322 is provided with the concave portion 322e which is recessed radially outward. Accordingly, the area of the upper surface of the rotation stopper portion 322 is reduced, and the accumulation of reaction products on the wafer guide 320 can be suppressed. Accordingly, the reaction products on the upper surface of the rotation stopper portion 322 can be suppressed from adhering to the wafer W during loading or unloading.

### Fourth Modified Example

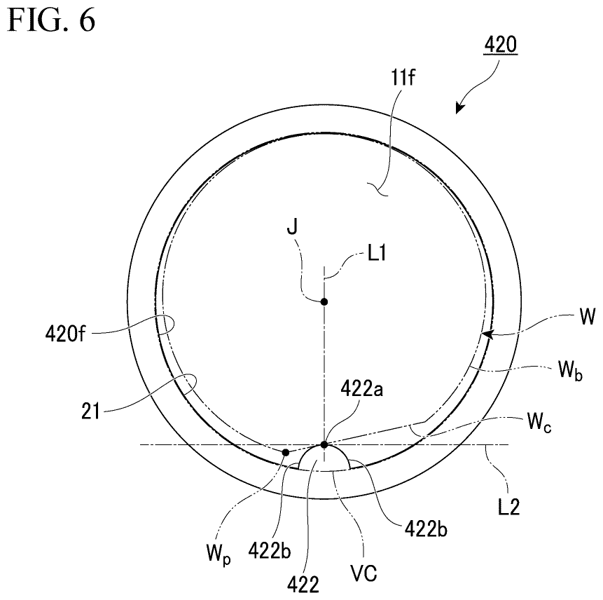

FIG. 6 is a plan view of a wafer guide 420 of a fourth modified example that can be used in the susceptor 10 of the above-described embodiment. The wafer guide 420 of this modified example differs from the above-described embodiment mainly in the shape of the rotation stopper portion 422.

As in the above-described embodiment, an inner peripheral surface 420f of the wafer guide 420 of this modified example is provided with the arc portion 21 which extends on the virtual circle VC and a rotation stopper portion 422 which is located radially inside the virtual circle.

The rotation stopper portion 422 of this modified example has a semicircular shape when viewed from the axial direction. The rotation stopper portion 422 has a tip portion 422a and a pair of side portions 422b. The tip portion 422a is located at the radially inner end of the rotation stopper portion 422. The side portions 422b are located on both circumferential sides of the tip portion. The side portions 422b extend radially outward from the tip portion 422a. Further, the side portions 422b are connected to the arc portion 21. The entire side portion 422b of this modified example is a curved surface. According to this modified example, the rotation can be restricted by bringing the flat portion Wc of the wafer W that slides and rotates on the support surface 11f into contact with the curved surface. Accordingly, the application of a large local force to the flat portion Wc of the wafer W can be suppressed.

According to at least one of the above-described embodiments, since the wafer guides 20, 120, 220, 320, and 420 with the rotation stopper portions 22, 122, 222, 322, and 422 having the side portions 22b, 122b, 222b, 322b, and 422b formed on the inner peripheral surfaces 20f, 120f, 220f, 320f, and 420f are provided, it is possible to prevent interference with unloading of the wafer W while suppressing the wafer W from sliding and rotating.

While certain embodiments have been described, these embodiments have been presented only as exemplary examples, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A susceptor comprising:
a support base which has a support surface for supporting a wafer; and
an annular wafer guide which surrounds the periphery of the wafer supported on the support surface with a center axis extending in a normal direction of the support surface as a center,
wherein an inner peripheral surface of the wafer guide when viewed from an axial direction of the center axis is provided with an arc-shaped arc portion extending on a virtual circle centered on the center axis and a rotation stopper portion having at least a part located radially inside the virtual circle, and
wherein the rotation stopper portion has a tip portion located at a radially inner end of the rotation stopper portion and a side portion located on at least one side of the tip portion in a circumferential direction centered on the center axis, extending radially outward from the tip portion, and connected to the arc portion.

2. The susceptor according to claim 1,
wherein the side portions are provided on one side and an other side of the tip portion in the circumferential direction, respectively.

3. The susceptor according to claim 1,
wherein the side portion is provided on one side of the tip portion in the circumferential direction, and
wherein an end on an other side of the tip portion in the circumferential direction is connected to the arc portion.

4. The susceptor according to claim 1,
wherein the rotation stopper portion is provided with a concave portion which is recessed radially outward.

5. The susceptor according to claim 1,
wherein the side portion has a chamfered portion or a curved surface provided in a portion connected to the tip portion.

6. The susceptor according to claim 1,
wherein an outer peripheral surface of the wafer is provided with a flat portion extending on a straight line, and
wherein a distance connecting two intersections between the rotation stopper portion and the virtual circle on one side and an other side in the circumferential direction is shorter than a length dimension of the flat portion when viewed from the axial direction.

7. A SiC epitaxial growth apparatus comprising:
a susceptor,
wherein the susceptor has a support base which has a support surface for supporting a wafer and an annular wafer guide which surrounds the periphery of the wafer supported on the support surface with a center axis extending in a normal direction of the support surface as a center,
wherein an inner peripheral surface of the wafer guide when viewed from an axial direction of the center axis is provided with an arc-shaped arc portion extending on a virtual circle centered on the center axis and a rotation stopper portion having at least a part located radially inside the virtual circle, and
wherein the rotation stopper portion has a tip portion located at a radially inner end of the rotation stopper portion and a side portion located on at least one side of the tip portion in a circumferential direction centered on the center axis, extending radially outward from the tip portion, and connected to the arc portion.
